(19) United States
(12) Patent Application Publication
(10) Pub. No.: US 2024/0363786 A1
(43) Pub. Date: Oct. 31, 2024

(54) OPTICAL COMPONENT

(71) Applicant: UNIVERSITÄT SIEGEN, Siegen (DE)

(72) Inventors: Andreas BABLICH, Hennef (DE); Rainer BORNEMANN, Schmallenberg (DE); Peter HARING BOLIVAR, Wenden (DE); Maurice MÜLLER, Brubach (DE); Andreas NACHTIGAL, Kirchen (DE)

(21) Appl. No.: 18/291,119

(22) PCT Filed: Jul. 19, 2022
(86) PCT No.: PCT/EP2022/070197

§ 371 Date: Jan. 22, 2024

(30) Foreign Application Priority Data
Jul. 21, 2021 (DE) 10 2021 118 816.4

(51) Int. Cl. H01L 31/105; G01S 7/4861; G02F 1/35

(52) U.S. Cl. CPC H01L 31/1055; G01S 7/4861; G02F 1/353

(57) ABSTRACT

An optical component serves as a nonlinear photodetector for generating a nonlinear electrical signal. The component comprises a first electrically conductive layer, a second electrically conductive layer and an absorption layer. The absorption layer is arranged between the first and the second electrically conductive layer and has a layer thickness of at least 500 nm. The electrical signal is generated by the component by applying a voltage at the component and irradiating the component with electromagnetic radiation in a first wavelength range (λ1) with a radiation intensity of less than 10 nW/mm2 and also irradiating the optical component with electromagnetic radiation in a second wavelength range (λ2) that is different from the first wavelength range (λ1) and a radiation intensity of less than 100 nW/mm2.

### INTRODUCTION

The disclosure relates to the use of an optical component as a nonlinear photodetector for generating a nonlinear electrical signal.

Furthermore, the disclosure relates to the use of an optical component as a frequency mixer for mixing at least two optically induced electrical signals.

In addition, the disclosure relates to an optical component comprising a first electrically conductive layer, a second electrically conductive layer and an absorption layer, wherein the absorption layer is arranged between the first and the second electrically conductive layer and has a layer thickness of at least 500 nm.

The disclosure also relates to a photonic mixing detector for measuring the distance to an object by means of a time-of-flight method

A photodetector, such as a photodiode, a photoresistor, a photoconductor, a phototransistor or a solar cell, is an optical component, typically made of a semiconductor material such as silicon, which converts light into an electrical signal. For example, photodiodes generate a photocurrent on the basis of irradiated light. Photodetectors are used, for example, as sensor elements in image sensors. A photodetector is specified as linear if the electrical signal generated by the photodetector increases constantly with the irradiated radiant power ([Φₑ]=W, also known as radiant flux). Typical photodetectors made of semiconductor materials exhibit a linear behavior under everyday lighting with radiant powers of 10⁻¹² W to 10⁻² W.

By means of complex component architecture, additional circuit peripherals, for example photodiodes connected with capacitors, field-effect transistors and/or operational amplifiers, and with considerable computational effort, it is possible to generate a nonlinear behavior of the electrical signal. However, the nonlinear response of the system is not generated by the photodetector itself, but by the peripheral circuitry.

For example, logarithmic active pixel sensors (logarithmic APS) use field effect transistors to generate a logarithmic and therefore nonlinear dependency of the electrical signal on the irradiated radiant power. The disadvantage of this, however, apart from the use of additional active components, is the drastic reduction in switching speed with decreasing radiant power, which prevents fast imaging in low ambient light, for example.

It is known that nonlinear effects in optical sensors occur at high radiant power and therefore also at high radiation intensities ([Eₑ]=W/m2, radiant power per area, also known as intensity, area power density, power density or radiation flux density). In particular, elaborately manufactured InP/InGaAs heterostructure pin diodes, InP-based unipolar photodiodes or graphene-based photodiodes exhibit optical nonlinearities at high radiation intensities. Since the nonlinearities only occur at high radiation intensities, the use of lasers to generate the nonlinear behavior is essential. In addition, nonlinear optical sensors are generally inefficient, since the conversion ratio of the photocurrent to the radiation intensity is very low.

Sensors made from specifically designed photodiodes, so-called PMD sensors (photonic mixing device sensor), also known as photomixing detectors, are also used as image sensors in TOF cameras (time-of-flight cameras) to determine distances to objects by use of a time-of-flight method. For this purpose, the scene is illuminated by use of a modulated optical signal and the camera measures the time it takes for the optical signal to reach the object and return back again for each pixel. The time required is directly proportional to the distance via the speed of light in the medium, in this case air. The camera therefore provides the distance of the object imaged thereon for each pixel. The basic measuring principle thus corresponds to laser scanning of a single-pixel detector, with the difference that an entire scene is captured at once and does not have to be scanned point by point.

The image sensor of the TOF camera, i.e. the PMD sensor, measures the time of flight of the optical signal separately for each pixel. The PMD sensor is similar to other image sensors of digital cameras with the difference that a sensor element has a much more complex structure:
the sensor element must not simply be able to collect the incident light and generate a photocurrent therefrom, but must also offer the possibility of determining the time of flight of the optical signal by means of a complex evaluation of the electrical signal. The complex structure of PMD sensors results in a very low geometric fill factor, wherein the fill factor specifies the proportion of the light-sensitive image sensor surface area to the total surface area of the image sensor.

For time-of-flight measurement by use of PMD sensors, the optical signal emitted by a light source of the camera is modulated and the received signal reflected back by the object is mixed with an electrical reference signal. The mixing corresponds to a time-synchronous multiplication of the signal amplitudes. A cross-correlation is then used to determine the relative phase shift between the emitted and the received signal, whereby in turn the time of flight can be determined. In other words, the phase shift between an amplitude-modulated signal for the intensity of the light source and a push-pull modulated signal of the same frequency is measured. The latter push-pull signal ensures charge separation in the PMD sensor. The correlation of both signals is used for distance measurement.

Complex, frequency-stable driver, amplifier and switching stages must be integrated in the PMD sensor to generate an electrical reference frequency and the modulation frequency as well as for signal correlation, which considerably restricts the fill factor of the PMD sensor. This type of distance measurement also requires powerful, rapidly modulatable light sources whose maximum achievable radiant power influences the maximum measurable distance of the PMD sensor. The maximum radiant power of the light source is also restricted by the maximum permissible irradiation of the eye according to legal standards.

### SUMMARY

Based on this, it is an object per an embodiment of the disclosure to provide a nonlinear photodetector that exhibits a nonlinear electrical signal, preferably a nonlinear electrical response signal, even at low radiation intensities. In addition, it is an object per an embodiment of the disclosure to simplify the design of sensors for distance measurement.

In accordance with an embodiment of the disclosure, the object is achieved by use of an optical component as a nonlinear photodetector for generating a nonlinear electrical signal, wherein the component comprises a first electrically conductive layer, a second electrically conductive layer and an absorption layer, and wherein the absorption layer is arranged between the first and the second electrically conductive layer and has a layer thickness of at least 500 nm, wherein the electrical signal is generated by the component by applying a voltage to the component and illuminating the component with electromagnetic radiation in a first wavelength range with a radiation intensity of less than 10 nW/mm2 and additionally illuminating the optical component with electromagnetic radiation in a second wavelength range different from the first wavelength range and with a radiation intensity of less than 100 nW/mm2, and wherein, in a radiation intensity range of less than 100 W/mm2, a strength of the electrical signal depends nonlinearly on the applied voltage and/or nonlinearly on the radiation intensity of the electromagnetic radiation in the first and/or in the second wavelength range.

The core idea per an embodiment of the disclosure is to use the optical component, which comprises the first electrically conductive layer, the second electrically conductive layer and the absorption layer, wherein the absorption layer is arranged between the first and the second electrically conductive layer and has a layer thickness of at least 500 nm, as a nonlinear photodetector. The nonlinear electrical signal generated by use of the optical component makes it possible to simplify the design and manufacture of non-linear sensors, because downstream components—i.e. external peripherals—can be dispensed with. Preferably, the electrical signal is the response signal of the optical component, more preferably a current, and more preferably a photocurrent of the optical component. Further preferably the strength of the electrical signal is the current strength.

It was found that by irradiating the component with electromagnetic radiation in the first wavelength range λ₁ and additionally irradiating the optical component with electromagnetic radiation in the second wavelength range λ₂, which is different from the first wavelength range, a nonlinear electrical signal I is generated. The strength of the electrical signal I depends nonlinearly on the voltage U applied to the component. Alternatively, the strength of the electrical signal depends nonlinearly on the radiation intensity Eₑ ([Eₑ]=W/m2, radiant power per area) of the electromagnetic radiation in the first and/or in the second wavelength range. Preferably, the strength of the electrical signal depends nonlinearly on the applied voltage and nonlinearly on the radiation intensity of the electromagnetic radiation in the first and in the second wavelength range. The nonlinear behavior of the electrical signal does not only occur at very high radiation intensities, as expected, but already at everyday radiation intensities of the electromagnetic radiation in the first wavelength range of less than 10 nW/mm2 and of the electromagnetic radiation in the second wavelength range of less than 100 nW/mm2. The electrical signal also behaves nonlinearly in a radiation intensity range of less than 100 W/mm2, wherein radiation intensity refers to the total power of the incoming electromagnetic energy that hits the component per surface area through illumination with electromagnetic radiation. As already mentioned, the electrical signal behaves nonlinearly even at very low radiation intensities of less than 110 nW/mm2 due to illumination with electromagnetic radiation in the first and in the second wavelength range. Due to the low radiation intensities required, it is therefore not necessary to irradiate the component with lasers, laser diodes and/or other high-power light sources in order to generate the nonlinear electrical signal. Accordingly, the efficiency of the component used as a nonlinear photodetector is much higher than the efficiency of conventional nonlinear sensors.

Here, the nonlinearity of the electrical signal in dependence on the radiation intensity is not achieved by changing the area to be irradiated. In other words, the electrical signal generated by the component is also nonlinearly dependent on the radiant power of the electromagnetic radiation in the first wavelength range and/or on the radiant power of the electromagnetic radiation in the second wavelength range. It is further preferably provided that an irradiated area of the component is kept constant in size when the component is used as a nonlinear photodetector.

In addition, the nonlinearity of the electrical signal is generated by the component itself and not by additional downstream components. This means that the nonlinear electrical signal can be generated directly by irradiating and applying the voltage by use of a very simple component that is moreover easy to manufacture.

With regard to the component, it is provided that the layer thickness of the absorption layer is at least 500 nm. It has been found that the nonlinearity of the photocurrent disappears with thinner absorption layers. Preferably, it is provided that the layer thickness of the absorption layers is at least 1000 nm, more preferably at least 1200 nm, particularly preferably at least 1500 nm. It has been shown that the effect of the nonlinearity of the electrical signal is more pronounced with higher layer thicknesses of the absorption layer. With regard to an upper limit of the layer thickness, it is further preferably provided that the layer thickness of the absorption layers is not more than 5000 nm. In addition, it is preferably provided that the absorption layer is designed such that it absorbs at least a portion of the electromagnetic radiation in the first wavelength range and/or a portion of the electromagnetic radiation in the second wavelength range.

With regard to the photodetector, it is preferably provided that the nonlinear photodetector is designed as a nonlinear photodiode, a nonlinear photoresistor, a nonlinear photoconductor, a nonlinear phototransistor and/or a nonlinear solar cell.

It is further preferably provided that the strength of the electrical signal generated by the component does not correspond to a sum of individual electrical signals generated by the component, wherein the individual electrical signal is respectively generated by the component by applying the voltage to the component and illuminating the component with the electromagnetic radiation in the first wavelength range with a radiation intensity of less than 10 nW/mm2 or by applying the voltage to the component and illuminating the optical component with the electromagnetic radiation in the second wavelength range, which is different from the first wavelength range, with a radiation intensity of less than 100 nW/mm2.

In principle, it is possible that the electrical signal generated by the component is smaller than the sum of the individual electrical signals. According to a preferred further development of the invention, however, it is provided that the strength of the electrical signal generated by the component is greater than the sum of the individual electrical signals generated by the component, wherein the individual electrical signal is respectively generated by the component by applying the voltage to the component and illuminating the component with the electromagnetic radiation in the first wavelength range with the radiation intensity of less than 10 nW/mm2 or by applying the voltage to the component and illuminating the optical component with the electromagnetic radiation in the second wavelength range, which is different from the first wavelength range, with the radiation intensity of less than 100 nW/mm2.

In photodiodes, the current strength of the photocurrent—i.e. the strength of the electrical signal minus the dark current component—usually results from the sum of the individual electrical signals generated by irradiating with the electromagnetic radiation in the first wavelength range and by irradiating with the electromagnetic radiation in the second wavelength range, which are also referred to as individual photocurrents. This expected behavior can be expressed mathematically as follows, where I denotes the current intensity of the electrical signal, f (λ_{1,2}, U) denotes a wavelength- and voltage-dependent conversion factor to be determined experimentally and E_{1,2} denotes the radiation intensities, i.e. the radiant power per area of the electromagnetic radiation used for irradiation:

$$I = f ( {λ}_{1} , U ) \cdot {E}_{1} + f ( {λ}_{2} , U ) \cdot {E}_{2}$$

The two wavelength-and voltage-dependent conversion factors f (λ_{1,2}, U) can also be combined to a wavelength-and voltage-dependent factor K (λ₁, λ₂, U):

$$I = K ( {λ}_{1} , {λ}_{2} , U ) \cdot ( {E}_{1} + {E}_{2} )$$

For example, if, when irradiating a photodiode at a given voltage, a single photocurrent of 2.5 μA is achieved with red light (i.e. f(λ₁, U)·E₁=2.5 μA), and a single photocurrent of 3.5 μA is achieved with blue light (i.e. f(λ₂, U)·E₂=3.5 μA), it is to be expected that when the photodiode is simultaneously irradiated with red and blue light, the current strength of the photocurrent is 2.5 μA (red)+3.5 μA (blue)=6 μA.

In the present case, however, it has been found that the strength of the electrical signal generated by the component is not given by the sum of the strengths of the individual signals, but is greater than the sum of the individual signals. This behavior can be expressed mathematically as follows:

$$I > f ( {λ}_{1} , U ) \cdot {E}_{1} + f ( {λ}_{2} , U ) \cdot {E}_{2}$$

With reference to the numerical example above, a measurement of the strength of the electrical signal at the component did not produce the expected 6 μA, but 63 μA.

In this context, it is preferably provided, that when the component is used as a nonlinear photodetector, the sum of the individual electrical signals is amplified multiplicatively as a function of the radiation intensity of the electromagnetic radiation in the first wavelength range and/or in the second wavelength range. Multiplicatively amplified as a function of the radiation intensity of the electromagnetic radiation in the first wavelength range and/or in the second wavelength range means in this context that the electrical signal generated by the component corresponds to a multiplication of the sum of the individual electrical signals by a proportionality factor designated as P, wherein the proportionality factor depends on the radiation intensity E of the electromagnetic radiation in the first wavelength range and/or in the second wavelength range. Particularly preferably, the proportionality factor depends on the radiation intensity E1 of the electromagnetic radiation in the first wavelength range and on the radiation intensity E2 of the electromagnetic radiation in the second wavelength range. Further preferably, the proportionality factor depends on the applied voltage and preferably nonlinearly on the applied voltage. Mathematically, this behavior can be described as follows:

$$I = P ( {λ}_{1} , {λ}_{2} , U , {E}_{1} , {E}_{2} ) \cdot ( f ( {λ}_{1} , U ) \cdot {E}_{1} + f ( {λ}_{2} , U ) \cdot {E}_{2} )$$

The two wavelength-and voltage-dependent conversion factors f (λ_{1,2}, U) can also be combined with the radiation intensity-dependent proportionality factor to a wavelength-, voltage- and radiation intensity-dependent factor K(λ₁, λ₂, U, E₁, E₂):

$$I = K ( {λ}_{1} , {λ}_{2} , U , {E}_{1} , {E}_{2} ) \cdot ( {E}_{1} + {E}_{2} )$$

Compared to the behavior of known photodiodes, the proportionality factor P(λ₁, λ₂, U, E₁, E₂), by which the sum of the individual electrical signals is multiplied to obtain the strength of the electrical signal generated by the component, and/or the factor K(λ₁, λ₂, U, E₁, E₂), by which the sum of the radiation intensities E1 and E2 is multiplied to obtain the strength of the electrical signal generated by the component, is dependent on the radiation intensities E1, E2. Furthermore, it is provided that the radiation intensity-dependent proportionality factor P(λ₁, λ₂, U, E₁, E₂) and/or the radiation intensity-dependent factor K(λ₁, λ₂, U, E₁, E₂) is nonlinearly dependent on the applied voltage.

With regard to the applied voltage, according to another further development, it is provided that the voltage applied to the component is between −5 V and +3 V. This voltage range has proven to be particularly suitable for generating the non-linear electrical signal and/or for the multiplicative amplification of the sum of the individual electrical signals.

With regard to the electromagnetic radiation used to illuminate the component, according to a further development, it is provided that the first wavelength range and the second wavelength range are each between 350 nm and 850 nm. In other words, the component is thus illuminated with light from the part of the electromagnetic spectrum that is largely visible to the human eye. The electromagnetic radiation in the first wavelength range is different in wavelength from the electromagnetic radiation in the second wavelength range. In other words, the component is simultaneously illuminated with electromagnetic radiation of different wavelengths.

With regard to the electromagnetic radiation used to illuminate the component, according to a further development, it is provided that the electromagnetic radiation in the first wavelength range and/or the electromagnetic radiation in the second wavelength range is modulated. It is thus possible, for example, to illuminate the component with electromagnetic radiation in the first wave-length range with constant radiation intensity over time—for example with blue light—and at the same time with electromagnetic radiation in the second wavelength range, wherein the radiation intensity of the electromagnetic radiation in the second wavelength range—for example red light—varies over time. In other words, this can be implemented by amplitude modulation of the electromagnetic radiation. Alternatively, it can also be implemented by frequency modulation, i.e. the carrier frequency—i.e. the light color of the light—changes over time. It is also possible that not only the electromagnetic radiation in the first wavelength range or the electromagnetic radiation in the second wavelength range is modulated, but that the electromagnetic radiation of both wavelength ranges is modulated. It is further provided in this context that the nonlinear behavior of the electrical signal is maintained up to modulation frequencies of 10 MHz, particularly up to modulation frequencies of 100 MHz.

Furthermore, the object is achieved in accordance with an embodiment by use of an optical component as a frequency mixer for mixing at least two optically induced electrical signals, wherein the component comprises a first electrically conductive layer, a second electrically conductive layer and an absorption layer, and wherein the absorption layer is arranged between the first and the second electrically conductive layer and has a layer thickness of at least 500 nm, wherein the component generates an electrical signal comprising a sum frequency and/or a difference frequency of a first and a second modulation frequency by applying a voltage to the component and illuminating the component with a first modulated optical signal and a second modulated optical signal, wherein the first modulated optical signal comprises electromagnetic radiation having a first carrier wavelength and the first modulation frequency, and wherein the second modulated optical signal comprises electromagnetic radiation having a second carrier wavelength and the second modulation frequency.

The core idea per an embodiment is thus also to use the optical component which comprises the first electrically conductive layer, the second electrically conductive layer and the absorption layer, wherein the absorption layer is arranged between the first and the second electrically conductive layer and has a layer thickness of at least 500 nm, as a frequency mixer. This makes it possible to simplify the design and manufacture of sensors and, in particular, sensors for distance measurement.

It has been found that by irradiating the component with two modulated optical signals, frequency mixing takes place intrinsically within the component, i.e. without generating the frequency mixing by external circuits and/or components. The electrical signal generated by the component thus comprises the sum frequency and/or the difference frequency of the two modulation frequencies. Preferably, the electrical signal generated by the component comprises the sum frequency and the difference frequency of the two modulation frequencies. Here, the first and/or the second optical signal can be amplitude-modulated or frequency-modulated. It is also provided that the first carrier wavelength is different from the second carrier wavelength. In other words, the component is used as a passive electro-optical frequency mixer.

According to a further development, it is provided in this context that the electrical signal comprising the sum frequency and/or the difference frequency is generated by the component at radiation intensities of the first optical signal and/or the second optical signal of less than 10 nW/mm2. Frequency mixing in photodiodes usually only takes place at high radiation intensities. In the present case, frequency mixing already takes place at everyday radiation intensities of less than 10 nW/mm2.

According to another further development, it is also provided that the first and/or the second carrier wavelength are in the wavelength range between 350 nm and 850 nm, and/or the first and/or the second modulation frequency are below 100 MHz. It has been shown that these values are advantageous for frequency mixing.

In addition, the object is achieved in accordance with an embodiment by use of an optical component as a sensor element in a photomixing detector for measuring a distance to an object by means of a time-of-flight method, wherein the component comprises a first electrically conductive layer, a second electrically conductive layer and an absorption layer and wherein the absorption layer is arranged between the first and the second electrically conductive layer and has a layer thickness of at least 500 nm.

Due to the frequency mixing, the component can be used as a sensor element in photomixing detectors. As already mentioned, photomixing detectors, also known as PMD sensors, measure the time of flight of the light separately for each pixel. The intrinsic frequency mixing that takes place in the component makes it possible to dispense with downstream components and still fulfill the function of the PMD sensor

According to a further development, it is provided that when the optical component is used as a sensor element in the photomixing detector for distance measurement by means of the time-of-flight method, the optical component is illuminated with electromagnetic radiation through the first and/or the second electrically conductive layer. It is particularly provided that the illumination of the optical component with the electromagnetic radiation takes place through the first and the second electrically conductive layer. In other words, not only a front side of the photomixing detector is irradiated, but also a rear side. Particularly the illumination of the optical component takes place through the first electrically conductive layer simultaneously with the illumination through the second electrically conductive layer. This has the advantage that there is more freedom in arranging the light sources used for illumination.

According to another further development, it is provided that when the optical component is used as a sensor element in the photomixing detector, a voltage applied to the optical component is modulated. Since—as described for the use of the component as a nonlinear photodetector—the nonlinearity of the electrical signal depends on the applied voltage, the determination of the distance to the object can be simplified by modulating the applied voltage.

The object is further achieved in accordance with an embodiment by providing a photomixing detector for measuring the distance to an object by means of a time-of-flight method, comprising a plurality of sensor elements, wherein a sensor element is formed by a component comprising a first electrically conductive layer, a second electrically conductive layer and an absorption layer, wherein the absorption layer is arranged between the first and the second electrically conductive layer and has a layer thickness of at least 500 nm.

In other words, the individual sensor elements of the photomixing detector—which are also called pixels—are each formed by the component. The individual sensor elements can be arranged linearly—in this case, the photomixing detector is a one-dimensional image sensor, also known as a line sensor. Alternatively, the sensor elements are arranged in a two-dimensional array. Such a two-dimensional photomixing detector is also known as an area sensor. Preferably, the sensor elements are arranged in a two-dimensional array. Further, the sensor elements are arranged in a three-dimensional array, wherein the sensor elements are partially transparent in one plane. A three-dimensional photomixing detector of this type is also referred to as a stacked sensor or multilayer sensor.

It is further preferred that not only one sensor element of the plurality of sensor elements is formed by the component, but all sensor elements of the photomixing detector are respectively formed by the component.

Due to the nonlinearity and the frequency mixing, the structure of the photomixing detector can be greatly simplified by using the component as a sensor element in the photomixing detector and by the photomixing detector. The nonlinearity and the frequency mixing take place intrinsically in the component and do not require any additional elements. The component itself has a simple structure, so that the structure and manufacture of the photomixing detector is greatly simplified by use of the component as a sensor element.

For example, a distance measurement with two modulated optical signals can be realized as follows. The amplitude of the second modulated optical signal is controlled in such a way that the amplitude of the sum frequency of the electrical signal generated by the component is kept constant. Based on the signal attenuation due to the distance (1/r² law), the distance to the object can be determined.

According to a further development, it is provided, that the photomixing detector is designed in such a way that the first electrically conductive layer and the second electrically conductive layer of the component can be illuminated with electromagnetic radiation. In other words, the photomixing detector is designed in such a way that not only one side of the photomixing detector can be illuminated, but both sides. In this context, it is provided that the first and the second electrically conductive layers of the component are at least optically partially transparent to the electromagnetic radiation used for illumination. Further, the electromagnetic radiation used for illumination is electromagnetic radiation in the wavelength range from 350 nm to 850 nm.

According to another further development, it is moreover provided that the plurality of sensor elements of the photomixing detector are arranged in a three-dimensional array. Thus, a stacking arrangement of the sensor elements in the photomixing detector is provided, in which the individual sensor elements are stacked next to and on top of one another in all three spatial dimensions. It is further provided that those sensor elements arranged in a plane of the sensor elements which are arranged in a three-dimensional array each have an optical transmission of at least 50% for an optical signal along a normal direction of the plane.

With regard to the physical configuration of the component, according to a further development in connection with the absorption layer, it is provided that the absorption layer of the component has an average defect density of at least 10¹⁹ cm⁻³. The average defect density of the absorption layer can be determined experimentally by CV (capacity-voltage), ESR (electron spin resonance) or CPM (constant photocurrent method) measurements.

Without being bound to a specific theory, it is assumed that the average defect densities of at least 10¹⁹ cm⁻³ of the absorption layer in conjunction with the layer thickness of the absorption layer cause the electric field to collapse locally—namely at the side of the component facing the illumination—when the component is illuminated with electromagnetic radiation in the first wavelength range due to the large number of photogenerated charges. The E-field collapse reduces the path that a photogenerated charge can travel, so that the photogenerated charge cannot reach the electrically conductive layers of the component and therefore cannot contribute to the current strength of the photocurrent. The electric field is amplified by additional illumination of the component with the electromagnetic radiation in the second wavelength range and thus the path the photogenerated charge can travel is extended. This also leads to an increase in the photocurrent generated by the component, since more charge reaches the electrical contact and can be dissipated.

In connection with the absorption layer, it is provided that the absorption layer comprises a material with a high defect density, so that the average defect density of the absorption layer is at least 10¹⁹ cm⁻³. Preferably it is provided that the absorption layer comprises a material selected from the group comprising calcium telluride (CaTe), copper indium diselenide (CIS), copper zinc tin sulfide (CZTS), copper gallium diselenide (CGS), copper indium gallium diselenide (CIGS), lead (II)-sulfide (PbS), amorphous silicon, amorphous hydrogenated silicon, amorphous silicon carbide, amorphous hydrogenated silicon carbide, amorphous silicon germanium, amorphous hydrogenated silicon germanium, microcrystalline silicon, and nanocrystalline silicon. Furthermore, it is provided that the absorption layer comprises organic materials that are used for organic solar cells, in particular polymers. All these materials have a high defect density, so that an average defect density of the absorption layer of at least 10¹⁹ cm⁻³ can be achieved in a simple manner.

It is possible that the absorption layer is made of exactly one material. Alternatively, it is possible that the absorption layer comprises several different materials. The several materials can form the absorption layer as a mixture. It may also be provided that the absorption layer is formed from several layers of different materials.

With regard to the absorption layer, it is further provided that the absorption layer has an average carbon concentration of less than 20 atom-%. It has been shown that an average carbon concentration of more than 20 atom-% is detrimental to the nonlinearity of the electrical signal generated by the component and also detrimental to frequency mixing. The average carbon concentration can be detected experimentally by ToF-SIMS (Time of Flight Secondary lon Mass Spectroscopy) or XPS (X-ray photoelectron spectroscopy).

In this context, it is further provided that the absorption layer has an average saturation with hydrogen of 5 atom-% o to 42 atom-%. It has been shown that an average saturation with hydrogen below 20 atom-% is advantageous for the nonlinearity of the electrical signal generated by the component and the frequency mixing. The average saturation with hydrogen can be experimentally detected by Fourier transform infrared spectrometry (FTIR) or Raman spectroscopy.

With regard to the morphology of the material of the absorption layer, it is further provided that the absorption layer is amorphous, that the absorption layer comprises an amorphous material and/or that the absorption layer is made of exactly one amorphous material. Amorphous material is understood to mean a material whose atoms do not have an ordered long-range order. Whether a material is amorphous can be determined experimentally by use of TEM (transmission electron microscopy) and/or diffraction by use of X-rays or neutron radiation, for example GISAS (grazing-incidence small-angle scattering).

Preferably, the absorption layer comprises amorphous hydrogenated silicon. Particularly the absorption layer is made of amorphous hydrogenated silicon. Moreover, it is provided that the absorption layer is not formed from several layers of different materials.

With regard to the layer structure of the component, it is furthermore provided, in accordance with a further development, that
a) a first side of the absorption layer contacts the first electrically conductive layer and a second side of the absorption layer contacts the second electrically conductive layer, or
b) a p-doped layer is arranged between the first side of the absorption layer and the first electrically conductive layer, wherein the p-doped layer contacts the first side of the absorption layer and the first electrically conductive layer, and an n-doped layer is arranged between the second side of the absorption layer and the second electrically conductive layer, wherein the n-doped layer contacts the second side of the absorption layer and the second electrically conductive layer.

With regard to feature a), in other words, it is provided that the component comprises three layers, particularly exactly three layers, namely, in the order of their structure, the first electrically conductive layer, the absorption layer and the second electrically conductive layer. The structure of the component is therefore very simple. In order to be used as a nonlinear photodetector, as a frequency mixer and/or as a sensor element in a photomixing detector and/or in order to fulfill the respective function of a nonlinear photodetector, a frequency mixer and/or a sensor element in a photomixing detector, the component requires no further layers.

With regard to feature b), in other words, it is provided that the component comprises five layers, particularly exactly five layers, namely, in the order of their structure, the first electrically conductive layer, the p-doped layer, the absorption layer, the n-doped layer and the second electrically conductive layer. In this alternative, the component thus has the layer structure of a pin diode, wherein the i-layer (intrinsic layer) is formed by the absorption layer. The component does not require any further layers in order to be used as a nonlinear photodetector, a frequency mixer and/or a sensor element in a photomixing detector and/or to fulfill the respective function of a nonlinear photodetector, a frequency mixer and/or a sensor element in a photomixing detector.

According to another further development, it is moreover provided that the component comprises a substrate layer, wherein the substrate layer contacts a side of the first or the second electrically conductive layer facing away from the absorption layer. The substrate layer can, for example, be formed by a glass carrier. The substrate layer serves as a carrier for the component.

In connection with the illumination of the component, according to another further development, it is provided that the first electrically conductive layer, the second electrically conductive layer and/or the substrate layer have an optical transmission of at least 50% for the electromagnetic radiation in the first wavelength range and/or for the electromagnetic radiation in the second wavelength range. This is a simple way to ensure that the light used for illumination is not significantly absorbed by the component before reaching the absorption layer.

With regard to the materials of the electrically conductive layers, it is provided that the first and/or the second electrically conductive layer comprises a material selected from the group comprising indium tin oxide (ITO), antimony-doped tin oxide (ATO), fluorine-doped tin oxide (FTO), aluminum-doped zinc oxide (AZO), thin metal layers, ultrathin 2-dimensional materials, in particular graphene, and transition metal dichalcogenides.

Furthermore, according to an embodiment, an optical component comprising a first electrically conductive layer, a second electrically conductive layer and an absorption layer is provided, wherein the absorption layer is arranged between the first and the second electrically conductive layer and has a layer thickness of at least 500 nm, wherein the absorption layer is made of amorphous, hydrogenated silicon and has an average defect density of at least 10¹⁹ cm⁻³, and wherein
a) a first side of the absorption layer contacts the first electrically conductive layer and a second side of the absorption layer contacts the second electrically conductive layer, or
b) a p-doped layer is disposed between the first side of the absorption layer and the first electrically conductive layer, wherein the p-doped layer contacts the first side of the absorption layer and the first electrically conductive layer, and an n-doped layer is disposed between the second side of the absorption layer and the second electrically conductive layer, wherein the n-doped layer contacts the second side of the absorption layer and the second electrically conductive layer.

Also according to an embodiment, a photomixing detector for measuring the distance to an object by means of a time-of-flight method, comprising a plurality of sensor elements is provided, wherein a sensor element is formed by the above component.

With regard to the features and advantages of such an optical component and such a photomixing detector, reference is made to the description of the use of the component as a nonlinear photodetector, as a frequency mixer and/or as a sensor element in the photomixing detector.

### BRIEF DESCRIPTION OF THE FIGURES

In the following, the invention is explained with reference to the drawing based on exemplary embodiments; in the drawing:

FIG. 1 shows a schematic representation of a component according to an embodiment;

FIG. 2 shows a block diagram of a component which, according to an embodiment, is used as a nonlinear photodiode;

FIG. 3 shows a schematic representation of a measurement setup in which a component according to a further embodiment is used as a nonlinear photodiode;

FIG. 4 shows a schematic representation of a current-voltage curve when using the component as in FIG. 3;

FIG. 5 shows a schematic representation of an amplification factor as a function of an expected measurement value from FIG. 4;

FIG. 6 shows a schematic representation of amplitude signals of the component when using the component as in FIG. 3; and

FIG. 7 shows a schematic representation of a photocurrent and its Fourier transformation of a component used as a frequency mixer according to a further embodiment.

### DETAILED DESCRIPTION

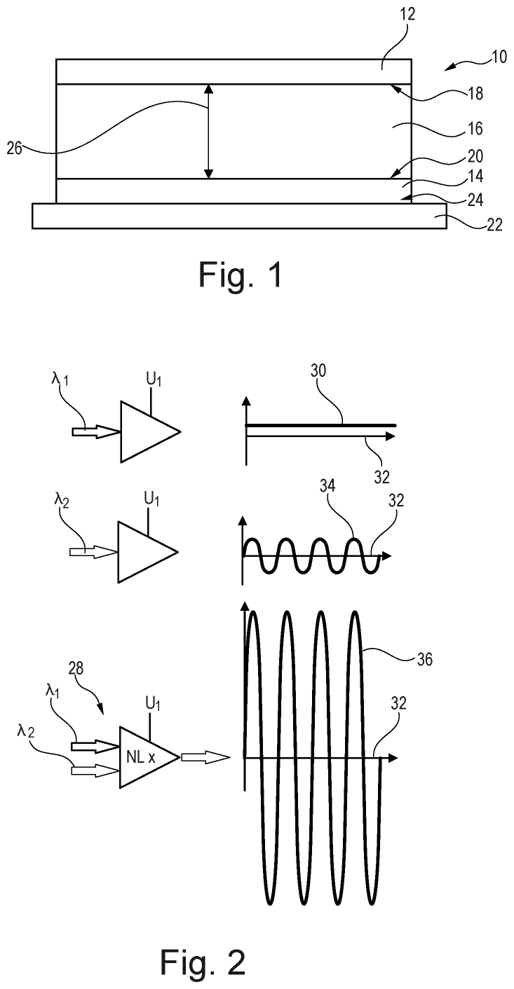

FIG. 1 shows a schematic representation of an optical component 10 according to an embodiment. The component comprises a first electrically conductive layer 12, a second electrically conductive layer 14 and an absorption layer 16, wherein the absorption layer 16 is arranged between the first electrically conductive layer 12 and the second electrically conductive layer 14. In the present case, no further layers are present between the first electrically conductive layer 12 and the second electrically conductive layer 14, so that a first side 18 of the absorption layer 16 contacts the first electrically conductive layer 12 and a second side 20 of the absorption layer 16 contacts the second electrically conductive layer 14. In the present exemplary embodiment the component 10 also comprises a substrate layer 22. The substrate layer 22, which is formed as a glass carrier, contacts a side 24 of the second electrically conductive layer 14 facing away from the absorption layer 16.

In the present case, the absorption layer 16 has a layer thickness 26 of 500 nm. In addition, the absorption layer 16 has an average defect density of at least 10¹⁹ cm⁻³. In the embodiment the absorption layer 16 is made of amorphous hydrogenated silicon.

FIG. 2 shows a block diagram of a component 10 which, according to an embodiment, is used as a nonlinear photodetector 28, in the present embodiment as a nonlinear photodiode 28. The block diagram illustrates the function of the component 10 as a nonlinear photodiode 28 and does not itself represent the component 10. By applying a voltage U₁ to the component 10 and illuminating the component 10 with electromagnetic radiation in a first wavelength range λ₁, the component 10 generates a first individual electrical signal 30, in the present case a first individual photocurrent 30 (FIG. 2 top). In the present case red light at a wavelength of 633 nm is used for irradiation, wherein the radiation intensity of the light is constant over time. Accordingly, the single photocurrent 30 shows no variation over time 32.

In addition, by applying the voltage U₁ to the component 10 and illuminating the component 10 with electromagnetic radiation in a second wavelength range λ₂, the component 10 generates a second individual electrical signal 34, in the present case a second individual photocurrent 34 (FIG. 2 center). In the present case, blue light at a wavelength of 477 nm is used for irradiation, wherein a radiation intensity of the light is modulated. The second individual electrical signal 34 exhibits correspondingly a changing intensity over time 32.

When the voltage U₁ is applied to the component 10 and the component 10 is illuminated with electromagnetic radiation in the first wavelength range λ₁ and simultaneously with electromagnetic radiation in the second wavelength range λ₂, the component 10 generates an electrical signal 36, the magnitude of which is greater than the expected sum of the individual electrical signals 30 and 34. Instead, the strength of the electrical signal 36 is given by multiplying the sum of the individual electrical signals by an radiation intensity-dependent proportionality factor, wherein the proportionality factor is dependent on the radiation intensity of the electromagnetic radiation in the first wavelength range λ₁ and the radiation intensity of the electromagnetic radiation in the second wavelength range λ₂.

Here, the component 10 in FIG. 2 is constructed as shown in FIG. 1, but can also be constructed as shown in FIG. 3 and described below.

FIG. 3 shows a schematic representation of a measurement setup in which a component 10 according to a further embodiment is used as a nonlinear photodetector 28, in this case as a nonlinear photodiode 28. In the present case, the component 10 comprises five layers, namely the first electrically conductive layer 12, the second electrically conductive layer 14 and the absorption layer 16, which is arranged between the first electrically conductive layer 12 and the second electrically conductive layer 14. In addition, a p-doped layer 40 is arranged between the first side 18 of the absorption layer 16 and the first electrically conductive layer 12, wherein the p-doped layer 40 contacts the first side 18 of the absorption layer 16 and the first electrically conductive layer 12. Likewise, an n-doped layer 38 is disposed between the second side 20 of the absorption layer 16 and the second electrically conductive layer 14, wherein the n-doped layer 38 contacts the second side 20 of the absorption layer 16 and the second electrically conductive layer 14. The first electrically conductive layer 12 and the second electrically conductive layer 14 are in the present case made of indium tin oxide. The absorption layer 16 is made of amorphous, hydrogenated silicon. The layer thickness 26 of the absorption layer 16 is in the present case 1500 nm. The component 10 is disposed on a glass carrier 22, which was glued into a chip housing and contacted with the chip housing (chip housing not shown in FIG. 3). The chip housing was attached to a base and the component 10 was connected to a current/voltage converter module 41. The current/voltage converter module 41 is used to set the voltage. The output of the current/voltage converter module 41 was connected to a multifunction board comprising a digital oscilloscope (not shown in FIG. 3) in order to record measurement data. The multifunction board controls various illumination sources 43—in the present case illumination sources 43 that emit electromagnetic radiation in the wavelength ranges λ₃, λ₆, λ₇, λ₈ and λ₉. The illumination sources 43 and the component 10 are disposed within an integrating sphere 42. The illumination sources 43, which emit the electromagnetic radiation with the wavelength λ₆ are in this case a modulated LED, which emits modulated electromagnetic radiation with a wavelength of 633 nm. The other illumination source 43, which emits electromagnetic radiation in the wavelength range λ₃, is in the present case a laser with a wavelength of 477 nm. The illumination source 43 that emits the electromagnetic radiation with the wave-lengths λ_{7,8,9} is an RGB LED that emits a constant, non-modulated backlight with a wavelength of optionally 450 nm, 520 nm and/or 633 nm.

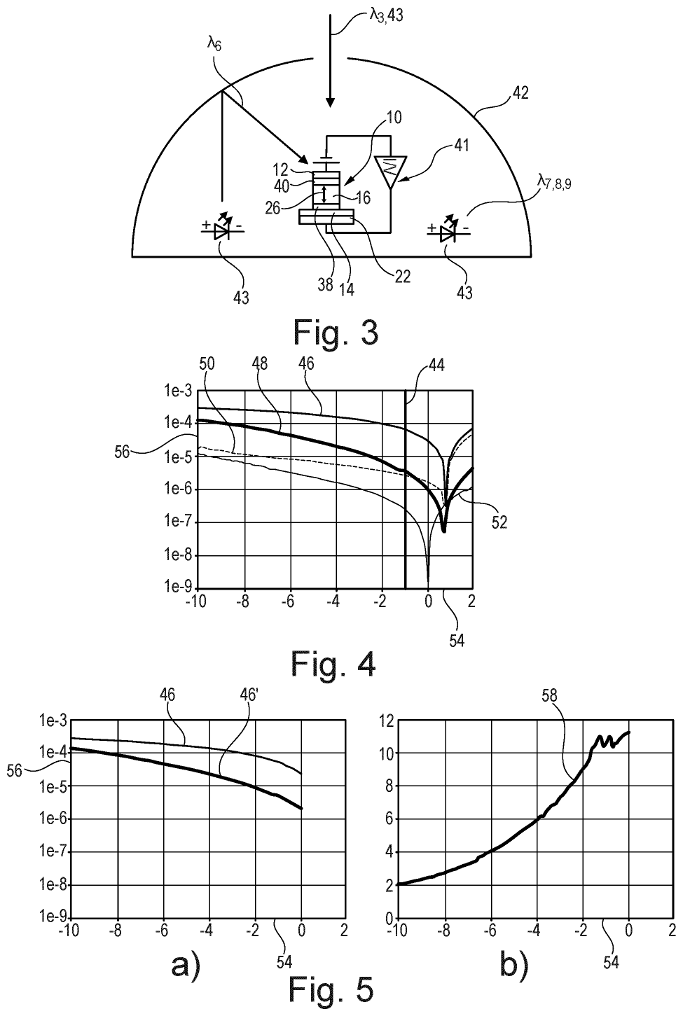

FIG. 4 shows exemplary curves of the electrical signal 46 and the individual electrical signals 48, 50 of the component 10 from FIG. 3 as a function of an externally applied voltage 54. The strength 56 of the electrical signal 46 or the individual electrical signals 48, 50, in this case the diode current strength, is plotted on the y-axis in amperes, and the applied voltage 54 is plotted on the x-axis in volts. In the dark case—i.e. with no illumination at all—the diode current 56 of the dark current 52 is, as expected, lower than in various illumination situations. In FIG. 3, the voltage-dependent curves of the electrical signal 46 and the individual electrical signals 48, 50 of the component 10 for the following illumination situations are shown in addition to the dark case:
illumination situation for the individual electrical signal 50: illumination with constant background lighting with red LED radiation λ₉ at 633 nm,
illumination situation for the individual electrical signal 48: illumination with laser radiation λ₃ at 477 nm,
illumination situation for the electrical signal 46: illumination with constant background lighting with red LED radiation λ₉ at 633 nm and simultaneously with laser radiation λ₃ at 477 nm.

In addition, the vertical line 44 in FIG. 4 exemplarily marks the resulting strength 56 of the electrical signal 46 or the individual electrical signals 48, 50 at a voltage 54 of −1 V. In the illumination situation for the individual electrical signal 50 with red LED a strength 56 of the individual electrical signal of 2.5 μA is generated at a voltage of −1 V. In the illumination situation for the individual electrical signal 48 with blue laser, a strength 56 of the individual electrical signal of 3.5 μA is generated at a voltage of −1 V.

In the illumination situation for the electrical signal 46 with red LED and blue laser, a strength 56 of the electrical signal of 63 μA is generated at a voltage of −1 V. With photodiodes, the strength 56 of the electrical signal is usually obtained from the sum of the strengths of the individual electrical signals generated by each light color. In the illumination situation for the electrical signal 46 at a voltage 54 of −1 V, the component 10 thus shows a strength 56 of the electrical signal 46 that is approximately 10.5 times higher than the expected sum of the strengths of the individual electrical signals 48, 50 of 6 μA, (3.5 μA+2.5 μA=6 μA). In the present case, the dark current 52 is more than an order of magnitude lower than the individual electrical signals 48, 50, so that it plays a negligible role in this consideration.

FIG. 5a compares the measured electrical signal 46 with the expected sum 46′ of the individual electrical signals 48, 50, while FIG. 5b shows the amplification factor 58 between the expected sum 46′ of the individual electrical signals 48, 50 and the measured electrical signal 46. The amplification factor 58 can be controlled by the applied voltage 54. In addition, the amplification factor 58 and thus the electrical signal 46 generated by the component 10 is nonlinearly dependent on the applied voltage 54.

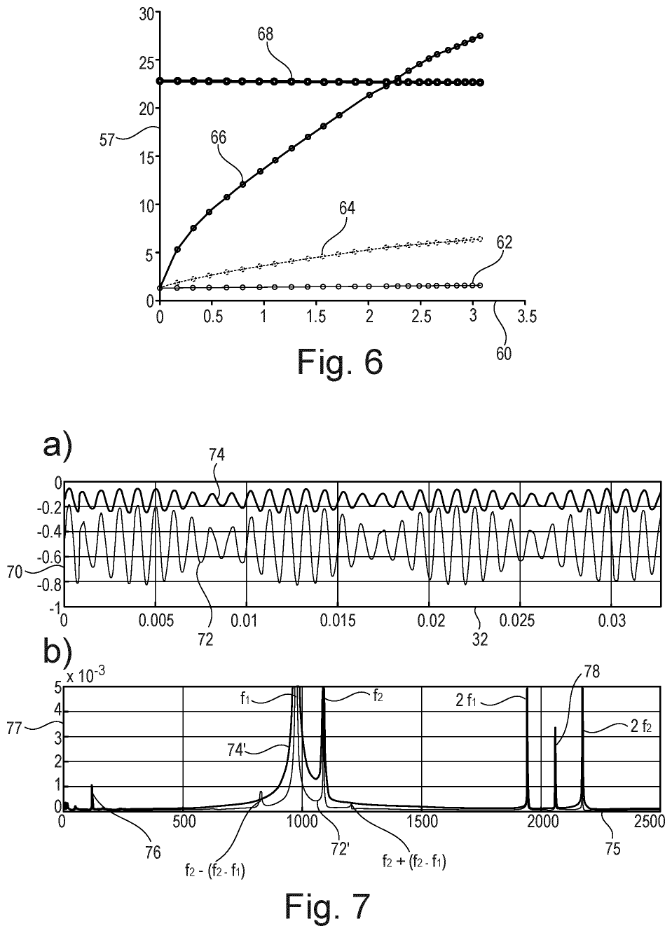

In addition to the applied voltage 54, the strength 56 of the electrical signal of the component 10 also depends on the radiation intensity 60 of the irradiation. FIG. 6 shows exemplary amplitude signals 62, 64, 66 of the electrical signal of the component 10 when illuminated with modulated blue laser radiation λ₃ at 477 nm as a function of different background illumination situations with constant, non-modulated background illumination with red, green and/or blue LED radiation λ_{7,8,9}. The amplitude 57 of the electrical signal of the component 10 is shown on the y-axis in μW/mm2. If the spectral sensitivity of the component 10 is known, the amplitude 57 of the electrical signal generated by the component 10 corresponds to the radiation intensity incident on the component 10. The radiation intensity 60 of the constant backlight λ_{7,8,9} is shown on the x-axis in μW/mm2. The following illumination situations are shown:
illumination situation for the amplitude signal 62: illumination with modulated blue laser light λ₃ at 477 nm and with constantly illuminated blue LED radiation λ₇ at 450 nm with increasing radiation intensity 60,
illumination situation for the amplitude signal 64: illumination with modulated blue laser light λ₃ at 477 nm and with constantly illuminated green LED radiation λ₈ at 520 nm with increasing radiation intensity 60,
illumination situation for the amplitude signal 66: illumination with modulated blue laser light λ₃ at 477 nm and with constantly illuminated red LED radiation λ₉ at 633 nm with increasing radiation intensity 60.

In particular in the illumination situations for the amplitude signals 64 and 66, additional exposure of the component 10 to green or red LED radiation generates an amplitude signal 64, 66 of the electrical signal of the component 10, the amplitude 57 of which is nonlinearly dependent on the radiation intensity 60 of the LED radiation λ_{7,8}.

For comparison, FIG. 6 also shows the amplitude signal 68 of a commercially available crystalline silicon phosphor diode (Hamamatsu S2386-8K). The amplitude signal 68 in the commercially available silicon diode caused by the blue laser radiation λ₃ remains constant and cannot be influenced by the additional LED illumination. Since the amplitude signal 68 of the photodiode does not change, all three measurement curves of the three illumination situations are superimposed, so that only one measurement curve for the amplitude signal 68 can be seen in FIG. 6.

In contrast, simultaneous illumination of the component 10 with a red LED and a blue laser leads to a massive increase in the amplitude signal 66, the amplitude 57 of which even exceeds the value of the commercially available photodiode.

FIG. 7 shows in FIG. 7a a schematic representation of a section of a time-dependent electrical signal 72 and in FIG. 7b its Fourier transformation 72′ from the component 10 from FIG. 3 used as a frequency mixer in accordance with a further embodiment. In FIG. 7a, the voltage 70 in volts of the digital oscilloscope used to measure the electrical signal 72 is plotted on the y-axis, and the time 32 in seconds is plotted on the x-axis. The component 10 was simultaneously irradiated with modulated blue laser radiation λ₃ at 477 nm and a modulation frequency of 971 Hz and with modulated red LED radiation λ₆ at 633 nm and a modulation frequency of 1087 Hz. The electrical signal 72 generated by the component 10 was amplified and transformed to the frequency space 75 by means of a Fast Fourier Transformation. In FIG. 7b, the modulation amplitude 77 in volts is plotted on the y-axis and the frequency 75 in hertz on the x-axis. In addition to the expected fundamental frequencies f₁, f₂ and their harmonics 2·f₁, 2·f₂, a purely passive intrinsic frequency mixing takes place in the component 10, which can be seen in the generation of the difference frequency 76 with the magnitude f₂-f₁ and the sum frequency 78 with the magnitude f₁+f₂.

For comparison, FIG. 7 also shows an electrical signal 74 and its Fast Fourier Transformation 74′ from a commercially available photodiode. In the Fast Fourier Transformation 74′ of the electrical signal 74, only the fundamental frequencies f₁, f₂ and their harmonics 2·f₁, 2·f₂ are contained in the commercially available photodiode.

As used herein, the terms “general,” “generally,” and “approximately” are intended to account for the inherent degree of variance and imprecision that is often attributed to, and often accompanies, any design and manufacturing process, including engineering tolerances, and without deviation from the relevant functionality and intended outcome, such that mathematical precision and exactitude is not implied and, in some instances, is not possible.

All the features and advantages, including structural details, spatial arrangements and method steps, which follow from the claims, the description and the drawing can be fundamental to the invention both on their own and in different combinations. It is to be understood that the foregoing is a description of one or more preferred exemplary embodiments of the invention. The invention is not limited to the particular embodiment(s) disclosed herein, but rather is defined solely by the claims below. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “for example,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

### LIST OF REFERENCE NUMERALS

10 component
12 first electrically conductive layer
14 second electrically conductive layer
16 absorption layer
18 first side of absorption layer
20 second side of absorption layer
22 substrate layer, glass carrier
24 side of the second electrically conductive layer facing away from the absorption layer
26 layer thickness
28 nonlinear photodiode
30 individual electrical signal, first individual photocurrent
32 x-axis, time
34 individual electrical signal, second individual photocurrent
36 electrical signal, photocurrent
38 n-doped layer
40 p-doped layer
41 current/voltage converter module
42 integrating sphere
43 illumination sources
44 vertical line
46 electrical signal, photocurrent
46′ expected photocurrent, sum current from 48 and 50
48 individual electrical signal, photocurrent
50 individual electrical signal, photocurrent
52 dark current
54 x-axis, voltage
56 y-axis, current strength
57 y-axis, amplitude
58 amplification factor
60 radiation intensity
62 amplitude signal
64 amplitude signal

1. Use of an optical component as a nonlinear photodetector for generating a nonlinear electrical signal,
wherein the optical component comprises a first electrically conductive layer, a second electrically conductive layer and an absorption layer,
wherein the absorption layer is arranged between the first and the second electrically conductive layer and has a layer thickness of at least 500 nm,
wherein the nonlinear electrical signal is generated by the optical component by applying a voltage to the optical component and illuminating the optical component with electromagnetic radiation in a first wavelength range (λ₁) with a radiation intensity of less than 10 nW/mm² and additionally illuminating the optical component with electromagnetic radiation in a second wavelength range (λ₂) different from the first wavelength range (λ₁) and with a radiation intensity of less than 100 nW/mm², and
wherein in a radiation intensity range of less than 100 W/mm² a strength of the nonlinear electrical signal is nonlinearly dependent on the applied voltage (U₁) and/or nonlinearly dependent on the radiation intensity of the electromagnetic radiation in the first and/or in the second wavelength range (λ₁, λ₂).

2. Use according to claim 1, wherein the strength of the nonlinear electrical signal is greater than a sum of individual electrical signals generated by the optical component, wherein the individual electrical signal is respectively generated by the optical component by applying the voltage (U₁) to the optical component and illuminating the optical component with the electromagnetic radiation in the first wavelength range (λ₁) with the radiation intensity of less than 10 nW/mm² or by applying the voltage (U₁) to the optical component and illuminating the optical component with the electromagnetic radiation in the second wavelength range (λ₂) different from the first wavelength range (λ₁) and the radiation intensity of less than 100 nW/mm².

3. Use according to claim 2, wherein the sum of the individual electrical signals is multiplicatively amplified as a function of the radiation intensity of the electromagnetic radiation in the first wavelength range (λ₁) and/or in the second wavelength range (λ₂).

4. Use according to claim 1, wherein the voltage (U₁) applied to the optical component is between −5 V and +3 V.

5. Use according to claim 1, wherein the electromagnetic radiation in the first wavelength range (λ₁) and/or the electromagnetic radiation in the second wavelength range (λ₂) is modulated.

6. Use of an optical component as a frequency mixer for mixing at least two optically induced electrical signals,
wherein the optical component comprises a first electrically conductive layer, a second electrically conductive layer and an absorption layer,
wherein the absorption layer is arranged between the first and the second electrically conductive layer and has a layer thickness of at least 500 nm,
wherein the optical component generates an electrical signal having a sum frequency and/or a difference frequency of a first and a second modulation frequency (f₁, f₂) by applying a voltage (U₁) to the optical component and illuminating the optical component with a first modulated optical signal and a second modulated optical signal,
wherein the first modulated optical signal comprises electromagnetic radiation having a first carrier wavelength (λ₄) and the first modulation frequency (f₁), and wherein the second modulated optical signal comprises electromagnetic radiation having a second carrier wavelength (λ₆) and the second modulation frequency (f₂).

7. Use according to claim 6, wherein the electrical signal having the sum frequency and/or the difference frequency is generated by the optical component at radiation intensities of the first optical signal and/or the second optical signal of less than 10 nW/mm².

8. Use according to claim 6, wherein the first and/or the second carrier wavelength (λ₄, λ₆) is in the wavelength range between 350 nm and 850 nm, and/or wherein the first and/or the second modulation frequency (f₁, f₂) is below 100 MHz.

9. Use of an optical component as a sensor element in a photomixing detector for measuring a distance to an object via a time-of-flight method,
wherein the optical component comprises a first electrically conductive layer, a second electrically conductive layer and an absorption layer and
wherein the absorption layer is arranged between the first and the second electrically conductive layer and has a layer thickness of at least 500 nm,

10. Use according to claim 9, wherein the optical component is illuminated with electromagnetic radiation through the first and/or the second electrically conductive layer.

11. Use according to claim 9, wherein a voltage applied to the optical component is modulated.

12. Use according to claim 9,
wherein
a) a first side of the absorption layer contacts the first electrically conductive layer and a second side of the absorption layer contacts the second electrically conductive layer, or
b) a p-doped layer is disposed between the first side of the absorption layer and the first electrically conductive layer, wherein the p-doped layer contacts the first side of the absorption layer and the first electrically conductive layer, and wherein an n-doped layer is disposed between the second side of the absorption layer and the second electrically conductive layer, wherein the n-doped layer contacts the second side of the absorption layer and the second electrically conductive layer.

13. Use according to claim 9,
wherein the absorption layer of the component has an average defect density of at least 10¹⁹ cm⁻³.

14. Optical component comprising a first electrically conductive layer, a second electrically conductive layer and an absorption layer, wherein the absorption layer is arranged between the first and the second electrically conductive layer and has a layer thickness of at least 500 nm,
wherein the absorption layer is made of amorphous hydrogenated silicon and has an average defect density of at least 10¹⁹ cm⁻³, and wherein
a) a first side of the absorption layer contacts the first electrically conductive layer and a second side of the absorption layer contacts the second electrically conductive layer, or
b) a p-doped layer is arranged between the first side of the absorption layer and the first electrically conductive layer, wherein the p-doped layer contacts the first side of the absorption layer and the first electrically conductive layer, and an n-doped layer is arranged between the second side of the absorption layer and the second electrically conductive layer, wherein the n-doped layer contacts the second side of the absorption layer and the second electrically conductive layer.

15. Photomixing detector for measuring a distance to an object via a time-of-flight method, comprising a plurality of sensor elements, wherein a sensor element is formed from a component according to claim 14.

16. Photomixing detector according to claim 15,
wherein the photomixing detector is configured in such a way that the first electrically conductive layer and the second electrically conductive layer of the component can be illuminated with electromagnetic radiation.

17. Photomixing detector according to claim 15, wherein the plurality of sensor elements are arranged in a three-dimensional array.
